(19) United States
(12) Patent Application Publication
(10) Pub. No.: US 2008/0197438 A1
(43) Pub. Date: Aug. 21, 2008

(54) Sensor semiconductor device and manufacturing method thereof

(75) Inventors: Chang-Yueh Chan, Taichung (TW); Chien-Ping Huang, Taichung (TW); Tse-Wen Chang, Taichung Hsien (TW); Chih-Ming Huang, Hsinchu Hsein (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/070,003

(22) Filed: Feb. 14, 2008

(30) Foreign Application Priority Data
Feb. 16, 2007 (TW) 096106007

(51) Int. Cl. H01L 31/0203; H01L 31/18

(52) U.S. Cl. 257/434; 438/64; 257/E31.11

(57) ABSTRACT

This invention discloses a sensor semiconductor device and a manufacturing method thereof, including: providing a wafer having a plurality of sensor chips, forming a plurality of grooves between bond pads on active surfaces of the adjacent sensor chips; forming conductive traces in the grooves for electrically connecting the bond pads; mounting a transparent medium on the wafer for covering sensing areas of the sensor chips; thinning the sensor chips from the non-active surfaces down to the grooves, thereby exposing the conductive traces; cutting the wafer to separate the sensor chips; mounting the sensor chips on a substrate module having a plurality of substrates, electrically connecting the conductive traces to the substrates; providing an insulation material on the substrate module and between the sensor chips so as to encapsulate the sensor chips but expose the transparent medium; and cutting the substrate module to separate a plurality of resultant sensor semiconductor devices.

### BACKGROUND OF THE INVENTION

1. Field of the Invention

The present invention relates to sensor semiconductor devices and manufacturing methods thereof, and more particularly, to a wafer-level chip-scale packaged (WLCSP) sensor semiconductor device and a manufacturing method thereof.

2. Description of the Prior Art

It is known in the art that image sensor packaging involves mounting a sensor chip on a chip carrier element, electrically connecting the sensor chip and the chip carrier element by means of bonding wires, covering the upper surface of the sensor chip with glass, thereby allowing image light to be retrieved by the sensor chip. Afterward, at a system factory the fully packaged image sensor package is integrated into an external device, such as a printed circuit board (PCB), for use in digital still cameras (DSC), digital video cameras (DV), optical mouses, cellular phones, etc. Owing to ever-increasing information transmission capacity, miniaturization of electronic products, and trend of portability, great importance is increasingly attached to high input/out (I/O), high heat dissipation and scale-down integrated circuits, and in consequence integrated circuits tend to be packaged in such a way as to achieve high electrical performance and miniaturization. Hence, the semiconductor industry developed a wafer-level chip-scale packaged (WLCSP) sensor semiconductor device slightly larger than a sensor chip integrate thereinto and therefore fit for small-sized electronic products.

Referring to FIGS. 1A to 1E showing a sensor semiconductor device and a manufacturing method thereof disclosed in U.S. Pat. No. 6,646,289, the wafer 10A having a plurality of sensor chips 10 is provided, wherein extension traces 11 are formed between bond pads 101 on adjacent ones of the sensor chips 10 (as shown in FIG. 1A); glass 12 is mounted to the extension traces 11 through an adhesive layer 13 (as shown in FIG. 1B); the wafer 10A is thinned and a covered layer 14 is mounted to the back of the wafer 10A; slanted grooves 15 corresponding in position to borders between adjacent ones of the sensor chips 10 are formed by cutting or etching to penetrate the covered layer 14, wafer 10A, extension traces 11, and adhesive layer 13 and reach the glass 12 (as shown in FIG. 1C); the metal routing traces 16 is formed on the slanted grooves 15 and a portion of the covered layer 14 adjacent thereto; the metal routing traces 16 are electrically connected to the extension traces 11 (as shown in FIG. 1D); solder balls 17 are disposed on the metal routing traces 16 formed on the covered layer 14; the sensor chips 10 are cut and separated from each other so as to obtain the wafer-level chip-scale packaged (WLCSP) sensor semiconductor device (as shown in FIG. 1E). Also, similar technical features are disclosed in U.S. Pat. No. 6,777,767.

However, as regards the aforesaid sensor semiconductor device, owing to the slanted grooves formed on the back of the wafer, the flanks of the sensor semiconductor device are slanted too after the cutting process; in other words, the vertical cross-section of the sensor semiconductor device is an inverted trapezoid (planar width progressively decreases downward). There is an acute angle of contact between the metal routing traces formed at the flanks of the sensor semiconductor device and the extension traces of the bond pads on top of the chips, and thus the contact is likely to sever due to stress concentration. Moreover, it is the back of the wafer where the slanted grooves are formed during the manufacturing process, alignment of the slanted grooves to be formed is so difficult as to prevent connection of the metal routing traces and extension traces, and even damage the chips.

The metal routing traces exposed out of the sensor semiconductor device are susceptible to contamination and the resultant compromised reliability and, upon electrical connection with an external device (a printed circuit board, for example), likely to end up with a short circuit during a solder ball reflow process. Also, formation of the extension traces and metal routing traces makes the manufacturing process complicated and incurs high costs.

Accordingly, an issue calling for an urgent solution involves developing a wafer-level chip-scale packaged (WLCSP) sensor semiconductor device and a manufacturing method thereof, so as to prevent traces from being severed and exposed, and eliminate poor electrical connection of traces and chip damage by improving alignment when cutting a wafer.

### SUMMARY OF THE INVENTION

In light of the aforesaid drawbacks of the prior art, it is a primary objective of the present invention to disclose a sensor semiconductor device and a manufacturing method thereof so as to prevent trace connections from severing due to an acute angle of contact.

Another objective of the present invention is to disclose a sensor semiconductor device and a manufacturing method thereof so as to enhance reliability of traces which might otherwise be exposed and contaminated.

Yet another objective of the present invention is to disclose a sensor semiconductor device and a manufacturing method thereof so as to eliminate poor electrical connection of traces and chip damage which might otherwise arise from alignment errors made in cutting a wafer.

In order to achieve the above and other objectives, the present invention provides a manufacturing method for a sensor semiconductor device, comprising the steps of: providing a wafer having a plurality of sensor chips, wherein each of the sensor chips has an active surface and a non-active surface opposite thereto, a sensing area and a plurality of bond pads are provided on the active surface, and a plurality of grooves are formed between the bond pads on the active surfaces of adjacent ones of the sensor chips; forming conductive traces in the grooves for electrically connecting the bond pads on the active surfaces of adjacent ones of the sensor chips; mounting a transparent medium on the sensor chips for covering the sensing area thereof; thinning the sensor chips from the non-active surfaces down to the grooves, thereby exposing the conductive traces from the non-active surface; cutting the wafer such that the sensor chips each laterally formed with the conductive traces are separated from one another; mounting the sensor chips on a substrate module having a plurality of substrates aligned in matrix, electrically connecting the conductive traces of the sensor chips to the substrates; providing an insulation material on the substrate module and between the sensor chips so as to encapsulate the sensor chips but expose the transparent medium; and cutting the substrate module so as to separate a plurality of resultant sensor semiconductor devices from one another.

In addition to the manufacturing method, the present invention discloses a sensor semiconductor device, comprising: a substrate; a sensor chip having an active surface and a non-active surface opposite thereto, wherein a sensing area and a plurality of bond pads are provided on the active surface, and conductive traces extended to and electrically connected with the bond pads are formed at the flanks of the sensor chip, thereby allowing the conductive traces to be electrically connected to the substrate through an electrical conduction material; a transparent medium formed on the active surface of the sensor chip for covering the sensing area; and an insulation material encapsulating the sensor chip but exposing the transparent medium.

The manufacturing method for a sensor semiconductor device of the present invention essentially comprises: providing a wafer having a plurality of sensor chips, forming a plurality of grooves between bond pads on active surfaces of the adjacent sensor chips; forming conductive traces in the grooves for electrically connecting the bond pads on the active surfaces of the adjacent sensor chips; mounting a transparent medium on the wafer for covering sensing areas of the sensor chips; and thinning the sensor chips from the non-active surfaces down to the grooves, thereby exposing the conductive traces from the non-active surfaces. By contrast, it is disclosed in the prior art that the extension traces and the adhesive layer are formed in the non-active surfaces of the sensor chips (that is, the back of the wafer) and electrically connected to the bond pads of the sensor chips, and slanted grooves are formed down to the glass; and the metal routing traces are formed on the slanted grooves and a portion of the covered layer adjacent to the slanted grooves and electrically connected to the extension traces. Owing to an acute angle formed on the contact between the metal routing traces formed at the flanks of the sensor semiconductor device and the extension traces of the bond pads on top of the chips, the contact may crack due to the stress concentrated thereon in the prior art. Also, it is the back of the wafer where the slanted grooves are formed during the manufacturing process, alignment of the slanted grooves to be formed is so difficult as to prohibit connection of the metal routing traces and extension traces, and even damage the chips in the prior art. The manufacturing method for a sensor semiconductor device in the present invention overcomes the aforesaid drawbacks of the prior art. The manufacturing method of the present invention further comprises: cutting the wafer such that the sensor chips each laterally formed with the conductive traces are separated from one another; mounting the sensor chips on a substrate module having a plurality of substrates aligned in matrix, electrically connecting the conductive traces of the sensor chips to the substrates; providing an insulation material on the substrate module and between the sensor chips so as to encapsulate the sensor chips but expose the transparent medium; and cutting the substrate module so as to separate a plurality of resultant sensor semiconductor devices from one another. Accordingly, the manufacturing method for a sensor semiconductor device in the present invention enhances reliability of traces which might otherwise be compromised in the situation where the traces are exposed and contaminated.

### BRIEF DESCRIPTION OF THE DRAWINGS

FIGS. 1A to 1E are schematic views showing a wafer-level chip-scale packaged (WLCSP) sensor semiconductor device and a manufacturing method thereof disclosed in U.S. Pat. No. 6,646,289;

FIGS. 2A to 2I are schematic views showing a sensor semiconductor device and a manufacturing method thereof in accordance with the first preferred embodiment of the present invention; and

FIGS. 3A to 3F are schematic views showing a sensor semiconductor device and a manufacturing method thereof in accordance with the second preferred embodiment of the present invention.

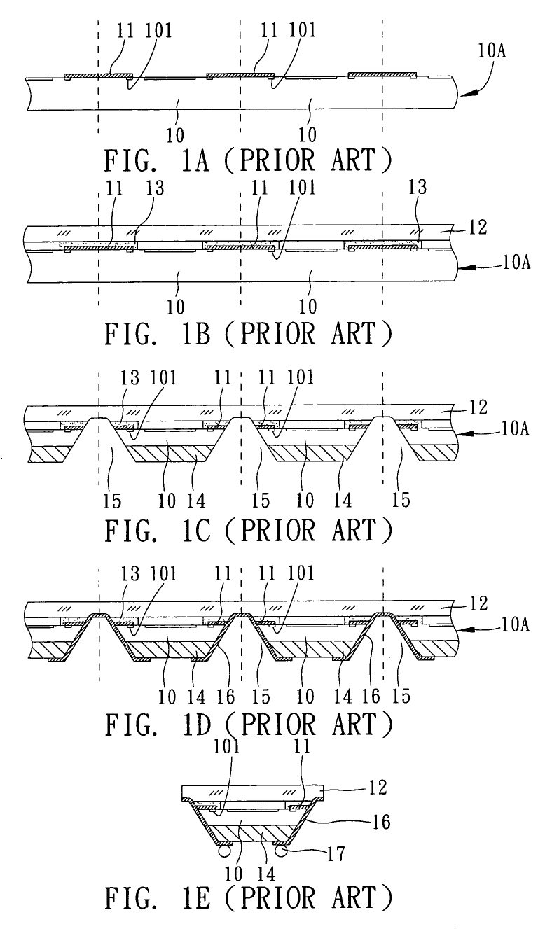

### DETAILED DESCRIPTION OF THE PREFERRED EMBODIMENTS

The following specific embodiments are provided to illustrate the present invention. Persons skilled in the art can readily gain insight into other advantages and features of the present invention based on the contents disclosed in this specification.

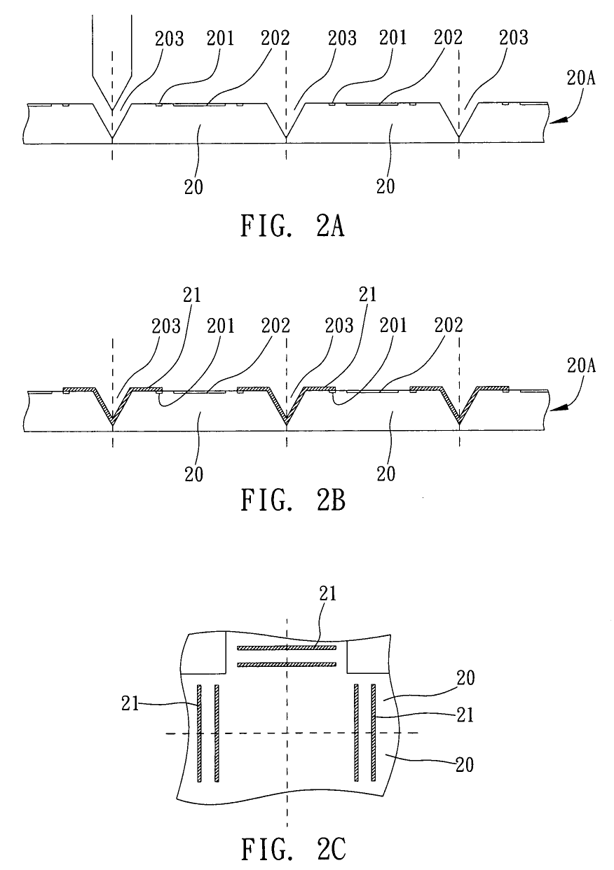

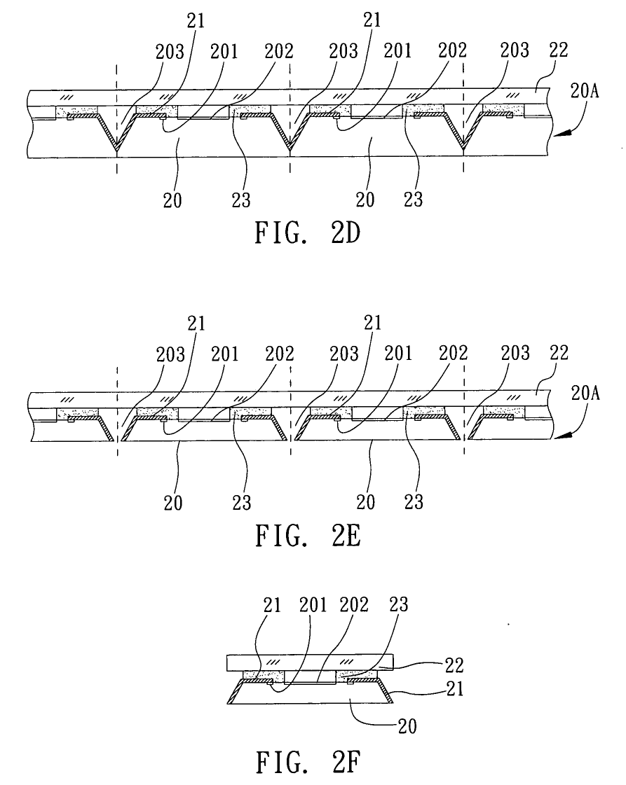

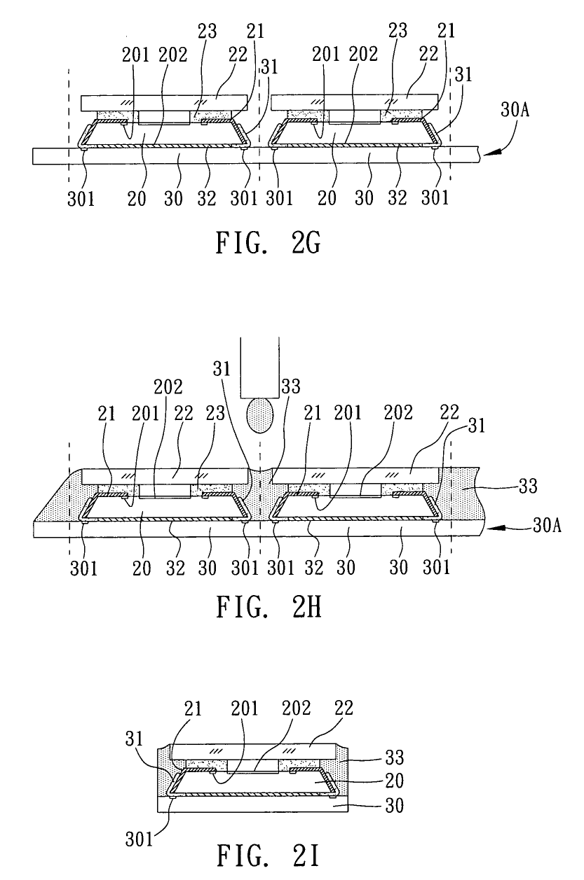

FIGS. 2A to 2I are schematic views showing the first preferred embodiment of a sensor semiconductor device and a manufacturing method thereof in accordance with the present invention. Mass production of the sensor semiconductor device of the present invention is described as follows.

Referring to FIG. 2A, a wafer 20A having a plurality of sensor chips 20 is provided, wherein each of the sensor chips 20 has an active surface and a non-active surface opposite thereto, a sensing area 202 and a plurality of bond pads 201 are provided on the active surfaces, and a plurality of grooves 203 are formed between the bond pads 201 on the active surfaces of adjacent ones of the sensor chips 20. The cross-section of the grooves 203 is V-shaped, U-shaped, or Y-shaped.

Referring to FIGS. 2B and 2C (FIG. 2C is the top plan view of FIG. 2B), the conductive traces 21 are formed in the grooves 203 for electrically connecting the bond pads 201 on the active surfaces of adjacent ones of the sensor chips 20 by sputtering, vaporizing or others. The conductive traces 21 are made of titanium/copper/nickel (Ti/Cu/Ni), titanium tungsten/gold (TiW/Au), aluminum/nickel-vanadium/copper (Al/NiV/Cu), titanium/nickel-vanadium/copper (Ti/NiV/Cu), titanium tungsten/nickel (TiW/Ni), titanium/copper/copper (Ti/Cu/Cu), or titanium/copper/copper/nickel (Ti/Cu/Cu/Ni).

As shown in FIG. 2D, a transparent medium 22 is mounted on the sensor chips 20 for covering the sensing area 202 thereof. The transparent medium 22 is glass, for example, and is mounted on the active surfaces of the sensor chips 20 through an adhesive layer 23 for sealing and covering the sensing area 202 of the sensor chips 20 by covering the conductive traces 21 on the sensor chips 20.

As shown in FIG. 2E, the sensor chips 20 are thinned from the non-active surfaces down to the grooves 203, such that the conductive traces 21 inside the grooves 203 are exposed from the non-active surfaces of the sensor chips 20.

As shown in FIG. 2F, the wafer 20A is cut along borders between the sensor chips 20, such that the sensor chips 20 each laterally formed with the conductive traces 21 are separated from one another, wherein the conductive traces 21 are electrically connected to the bond pads 201 on the active surfaces of the sensor chips 20, and the cutting path passes the transparent medium 22 and the sensor chips 20.

As shown in FIG. 2G, the sensor chips 20 are mounted on a substrate module 30A having a plurality of substrates 30 aligned in matrix, electrically connecting the conductive traces 21 of the sensor chips 20 to the substrates 30 by means of an electrical conduction material 31 like solder, for example.

A plurality of electrical contacts 301 are formed on the substrates 30 of the substrate module 30A. The electrical conduction material 31, such as pre-solder, is provided on the electrical contacts 301. With the sensor chips 20 being mounted on the substrates 30 through an adhesive layer 32, the electrical conduction material 31, is soldered to the conductive traces 21 flanking each of the sensor chips 20 in a reflow process, thus electrically connecting the sensor chips 20 to the substrates 30.

As shown in FIG. 2H, an insulation material 33 is disposed on the substrate module 30A and between the sensor chips 20 so as to encapsulate the sensor chips 20 but expose the transparent medium 22.

As shown in FIG. 2I, the substrate module 30A is cut along borders between the substrates 30, so as to separate a plurality of resultant sensor semiconductor devices from one another. In the situation where the substrates 30 are constructed as ball grid array substrates, a plurality of solder balls (not shown) are implanted on the sensor-chip-unmounted surface of the substrates 30, so as to allow the subsequently formed sensor semiconductor devices to be electrically connected to an external device.

The present invention further discloses a sensor semiconductor device comprising: a substrate 30; a sensor chip 20 having an active surface and a non-active surface opposite thereto, wherein a sensing area 202 and a plurality of bond pads 201 are provided on the active surface, and conductive traces 21 extended to and electrically connected with the bond pads 201 are formed at the flanks of the sensor chip 20, thereby allowing the conductive traces 21 to be electrically connected to the substrate 30 through an electrical conduction material 31; a transparent medium 22 formed on the active surface of the sensor chip 20 for covering the sensing area 202; and an insulation material 33 encapsulating the sensor chip 20 but exposing the transparent medium 22.

As regards the sensor semiconductor device of the present invention, the flanks of the sensor chip slope outward from the active surface of the sensor chip to the non-active surface of sensor chip, resulting in a trapezoidal cross-section of the sensor chip, wherein the planar width of the sensor chip progressively increases downward. As a result, stress concentration-induced severing of the obtuse bends of the conductive traces formed at the flanks, and extended and electrically connected to the bond pads on the active surface, of the sensor chip of the sensor semiconductor device of the present invention is rare.

The present invention discloses a sensor semiconductor device and a manufacturing method thereof. The manufacturing method of the present invention essentially comprises the steps of: providing a wafer having a plurality of sensor chips; forming a plurality of grooves between bond pads on the active surfaces of the adjacent sensor chips; forming conductive traces in the grooves for electrically connecting the bond pads on the active surfaces of the adjacent sensor chips; mounting a transparent medium on the wafer for covering sensing areas of the sensor chips; thinning the sensor chips from the non-active surfaces down to the grooves, thereby exposing the conductive traces from the non-active surfaces of the sensor chips. By contrast, it is disclosed in the prior art that the extension traces and the adhesive layer are formed in the non-active surfaces of the sensor chips (that is, the back of the wafer) and electrically connected to the bond pads of the sensor chips, and slanted grooves are formed down to the glass; and the metal routing traces are formed on the slanted grooves and a portion of the covered layer adjacent to the slanted grooves and electrically connected to the extension traces. Owing to an acute angle formed on the contact between the metal routing traces formed at the flanks of the sensor semiconductor device and the extension traces of the bond pads on top of the chips, the contact may crack due to the stress concentrated thereon in the prior art. Also, it is the back of the wafer where the slanted grooves are formed during the manufacturing process, alignment of the slanted grooves to be formed is so difficult as to prohibit connection of the metal routing traces and extension traces, and even damage the chips in the prior art. The manufacturing method of the present invention overcomes the aforesaid drawbacks of the prior art. The manufacturing method of the present invention further comprises: cutting the wafer along the borders of the sensor chips such that the sensor chips each laterally formed with the conductive traces are separated from one another; mounting the sensor chips on a substrate module having a plurality of substrates aligned in matrix, electrically connecting the conductive traces of the sensor chips to the substrates; providing an insulation material on the substrate module and between the sensor chips so as to encapsulate the sensor chips but expose the transparent medium; and cutting the substrate module along the borders of the substrates so as to separate a plurality of resultant sensor semiconductor devices from one another. Accordingly, the manufacturing method of the present invention enhances reliability of traces which might otherwise be compromised in the situation where the traces are exposed and contaminated and enhances reliability of the electrical connection of the traces and an external device.

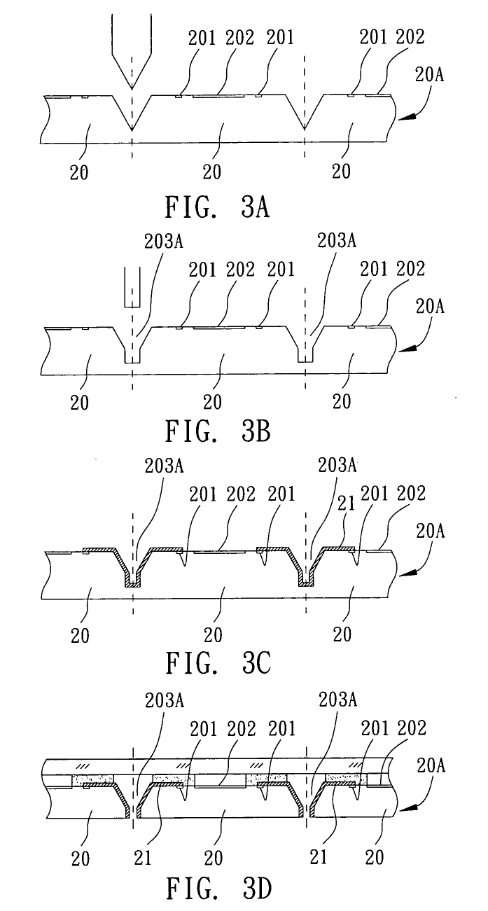

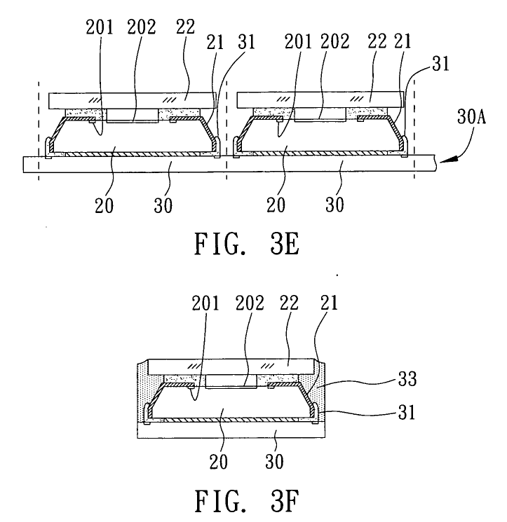

FIGS. 3A to 3F are schematic views showing the second preferred embodiment of a sensor semiconductor device and a manufacturing method thereof in accordance with the present invention. Like parts and components of the first and second preferred embodiments are denoted alike for the sake of brevity.

As shown in FIGS. 3A and 3B, a wafer 20A having a plurality of sensor chips 20 is provided, wherein each of the sensor chips 20 has an active surface and a non-active surface opposite thereto, a sensing area 202 and a plurality of bond pads 201 are provided on the active surface, and a plurality of grooves 203A are formed between the bond pads 201 on the active surfaces of adjacent ones of the sensor chips 20. A V-shaped cross-section of the grooves 203A is attained, using a V-shaped knife. Then, the V-shaped cross-section is turned into a Y-shaped cross-section, using a right-angled knife for cutting the bottom of the previously formed V-shaped grooves 203A.

As shown in FIG. 3C, the conductive traces 21 are formed in the grooves 203A for electrically connecting the bond pads 201 on the active surfaces of adjacent ones of the sensor chips 20.

As shown in FIG. 3D, the transparent medium 22 is mounted on the sensor chips 20 to seal and cover the sensing area 202 thereof, and thinning the sensor chips 20 from the non-active surfaces down to the grooves 203A, thereby exposing the conductive traces 21 from the non-active surfaces of the sensor chips 20.

As shown in FIG. 3E, the wafer 20A is cut along borders between the sensor chips 20, such that the sensor chips 20 each laterally formed with the conductive traces 21 are separated from one another, wherein the conductive traces 21 are electrically connected to the bond pads 201 on the active surfaces of the sensor chips 20, the sensor chips 20 are mounted on the substrate module 30A having the plurality of substrates 30, and the conductive traces 21 on the sensor chips 20 are electrically connected to the substrates 30 through the electrical conduction material 31, such as solder.

A point to note is that the conductive traces 21 are formed in the Y-shaped grooves 203A. Unlike the V-shaped grooves 203 formed in the first preferred embodiment, the flanks of the sensor chip 20 each include a sloping-flank portion and a vertical portion, the sloping-flank portion sloping outward from the active surface to the non-active surface. Therefore, the sensor chip 20 of the sensor semiconductor device of the second preferred embodiment is provided with a contact surface desirably and thereby coupled and electrically connected to the substrate 30 through the electrical conduction material 31 efficiently.

As shown in FIG. 3F, the insulation material 33 is filled on the substrate module 30A and between the sensor chips 20 so as to encapsulate the sensor chips 20 but expose the transparent medium 22, and cutting the substrate module 30A along borders between the substrates 30, so as to separate the plurality of resultant sensor semiconductor devices from one another.

The aforesaid embodiments merely serve as the preferred embodiments of the present invention. The aforesaid embodiments should not be construed as to limit the scope of the present invention in any way. Hence, many other changes can actually be made in the present invention. It will be apparent to those skilled in the art that all equivalent modifications or changes made to the present invention, without departing from the spirit and the technical concepts disclosed by the present invention, should fall within the scope of the appended claims.

What is claimed is:

1. A manufacturing method for a sensor semiconductor device, comprising the steps of:
providing a wafer having a plurality of sensor chips, wherein each of the sensor chips has an active surface and a non-active surface opposite thereto, a sensing area and a plurality of bond pads are provided on the active surface, and a plurality of grooves are formed between the bond pads on the active surfaces of adjacent ones of the sensor chips;
forming conductive traces in the grooves for electrically connecting the bond pads on the active surfaces of adjacent ones of the sensor chips;
mounting a transparent medium on the sensor chips for covering the sensing area of the sensor chip;
thinning the sensor chips from the non-active surfaces down to the grooves, thereby exposing the conductive traces from the non-active surface;
cutting the wafer along borders between the sensor chips, such that the sensor chips each laterally formed with the conductive traces are separated from one another;
mounting the sensor chips on a substrate module having a plurality of substrates aligned in matrix, and electrically connecting the conductive traces of the sensor chips to the substrates;
providing an insulation material on the substrate module and between the sensor chips so as to encapsulate the sensor chips but expose the transparent medium; and
cutting the substrate module along borders between the substrates, so as to separate a plurality of sensor semiconductor devices from one another.

2. The manufacturing method of claim 1, wherein the cross-section of the grooves is one selected from the group consisting of V-shaped, U-shaped, and Y-shaped structures.

3. The manufacturing method of claim 1, wherein the conductive traces are made of one selected from the group consisting of titanium/copper/nickel (Ti/Cu/Ni), titanium tungsten/gold (TiW/Au), aluminum/nickel-vanadium/copper (Al/NiV/Cu), titanium/nickel-vanadium/copper (Ti/NiV/Cu), titanium tungsten/nickel (TiW/Ni), titanium/copper/copper (Ti/Cu/Cu), and titanium/copper/copper/nickel (Ti/Cu/Cu/Ni).

4. The manufacturing method of claim 1, wherein the transparent medium is glass and is mounted on the active surfaces of the sensor chips through an adhesive layer for sealing and covering the sensing area of the sensor chips.

5. The manufacturing method of claim 1, wherein a plurality of electrical contacts are formed on the surface of the substrates, and an electrical conduction material is disposed above the electrical contacts, thereby allowing the sensor chips to be mounted on the substrates through an adhesive layer and electrically connected to the substrates through the electrical conduction material.

6. The manufacturing method of claim 5, wherein the electrical conduction material is a pre-solder material disposed above the substrates and soldered to the conductive traces of the sensor chips by a reflow process, thereby allowing the sensor chips to be electrically connected to the substrates.

7. A sensor semiconductor device, comprising:
a substrate;
a sensor chip having an active surface and a non-active surface opposite to the active surface, wherein a sensing area and a plurality of bond pads are formed on the active surface, and conductive traces extended to and electrically connected to the bond pads are formed at the flanks of the sensor chip, thereby allowing the conductive traces to be electrically connected to the substrate through an electrical conduction material;
a transparent medium formed on the active surface of the sensor chip for covering the sensing area; and
an insulation material for encapsulating the sensor chip but exposing the transparent medium.

8. The sensor semiconductor device of claim 7, wherein the conductive traces are made of one selected from the group consisting of titanium/copper/nickel (Ti/Cu/Ni), titanium tungsten/gold (TiW/Au), aluminum/nickel-vanadium/copper (Al/NiV/Cu), titanium/nickel-vanadium/copper (Ti/NiV/Cu), titanium tungsten/nickel (TiW/Ni), titanium/copper/copper (Ti/Cu/Cu), and titanium/copper/copper/nickel (Ti/Cu/Cu/Ni).

9. The sensor semiconductor device of claim 7, wherein the transparent medium is glass and is mounted on the active surface of the sensor chip through an adhesive layer for sealing and covering the sensing area of the sensor chip.

10. The sensor semiconductor device of claim 7, wherein a plurality of electrical contacts are formed on the surface of the substrate, and an electrical conduction material is disposed above the electrical contacts, thereby allowing the sensor chip to be mounted on the substrate through an adhesive layer and electrically connected to the substrate through the electrical conduction material.

11. The sensor semiconductor device of claim 7, wherein the flanks of the sensor chip slope outward from the active surface to the non-active surface.

12. The sensor semiconductor device of claim 7, wherein the flanks of the sensor chip each comprise a sloping-flank portion and a vertical portion, and the sloping-flank portion slops outward from the active surface to the non-active surface.
